(19) United States
(12) Patent Application Publication
(10) Pub. No.: US 2026/0082498 A1
(43) Pub. Date: Mar. 19, 2026

(54) SYSTEMS PROVIDING AIRFLOW FOR OPTOELECTRONIC DEVICE

(71) Applicant: Zhone Technologies, Inc., Plano, TX (US)

(72) Inventors: Lloyd Schenher, Almonte (CA); William Thomson, Ottawa (CA)

(73) Assignee: Zhone Technologies, Inc., Plano, TX (US)

(21) Appl. No.: 19/325,952

(22) Filed: Sep. 11, 2025

Related U.S. Application Data
(60) Provisional application No. 63/695,207, filed on Sep. 16, 2024.

(51) Int. Cl. H05K 5/03; H05K 5/02

(52) U.S. Cl. CPC H05K 5/03; H05K 5/0213

(57) ABSTRACT

A system may include a ventilation duct, which partially or completely surrounds a pluggable optoelectronic module. The pluggable optoelectronic module may be plugged into electronic equipment, which includes a fan to cause airflow from a front of the electronic equipment (where the pluggable optoelectronic module is plugged) to a rear of the electronic equipment. The ventilation duct may cause airflow to contact the pluggable optoelectronic module, such as at a heatsink of the pluggable optoelectronic module, as it goes from the ambient atmosphere to ventilation openings at the front of the electronic equipment.

### CROSS-REFERENCE TO RELATED APPLICATIONS

The present application claims the benefit of U.S. Provisional Patent Application 63/695,207, filed Sep. 16, 2024, the disclosure of which is hereby incorporated by reference in its entirety.

### TECHNICAL FIELD

The present disclosure relates to optoelectronic devices and, more specifically, to systems that provide airflow for optoelectronic devices.

### BACKGROUND

Optical networks, such as passive optical networks (PONs), have found widespread use in a variety of applications. For instance, residential and business Internet service providers may employ optical networks to transmit data to and from a home or business premises.

Optical networks may employ devices to convert optical data signals to electronic data signals. For example, pluggable optoelectronic interface modules are commonly used to connect optical fiber to electronic equipment. The features of these modules are typically governed by multi-source agreements, or MSAs. The electrical end of the pluggable module is typically inserted into the electronic equipment, while the optical interface end protrudes out the front of the equipment housing. An example of this is the quad small form factor pluggable double density (QSFP-DD) Type 1 module.

As pluggable modules have increased in speed and complexity, they have grown in length, and the optical interface has protruded farther out the front of the equipment housing, and thus farther from the heatsink inside the housing. An example of this is the QSFP-DD Type 2 module. Much of the heat is generated at the point near the front of the module where the optical signals are generated and received. On modules that protrude significantly from the front of the equipment housing the internal heatsink of the module may be too far away from the equipment housing to provide effective cooling.

### SUMMARY

Embodiments are directed to systems and methods for providing airflow for cooling for optoelectronic devices, such as for pluggable optoelectronic interface modules.

In one embodiment, a system includes: a housing having a front side and a rear side; and an opening in the housing from the front side to the rear side, and wherein the opening is configured to accommodate a pluggable module; further wherein the opening is configured to define a ventilation opening to cause airflow from the front side to the rear side in contact with the pluggable module.

In another embodiment, a system includes: a housing having a front side and a rear side; and an opening in the housing from the front side to the rear side, and wherein the opening is configured, at the rear side of the housing, to cover a first ventilation opening on a faceplate of an electronic equipment; further wherein the opening is configured to define a second ventilation opening, at the front side of the housing, to cause airflow from the front side of the housing to the first ventilation opening.

In yet another embodiment, a system includes: a housing having a front side, a rear side, a top side, and a bottom side; first translucent material disposed within the housing and extending from the front side to the rear side of the housing; and second translucent material disposed within the housing and extending from the front side to the rear side of the housing; wherein the housing is configured at the rear side to cover a plurality of ventilation openings on a faceplate of electronic equipment, and wherein the housing is configured at the front side to accommodate insertion of an optoelectronic pluggable module to be inserted through the housing from the front side to the rear side and into the faceplate of the electronic equipment, further wherein the housing is configured to define an additional ventilation opening to cause airflow to contact an outside surface of the optoelectronic pluggable module, and further wherein the first translucent material and the second translucent material are configured to transmit light signals from the faceplate to the front side of the housing.

### BRIEF DESCRIPTION OF THE DRAWINGS

Having thus described the invention in general terms, reference will now be made to the accompanying drawings, which are not necessarily drawn to scale, and wherein:

FIG. 1 is an illustration of an example system, including an example ventilation duct, according to some embodiments.

FIG. 2 is an illustration of the example ventilation duct of FIG. 1 according to a front view and a rear view, according to some embodiments.

FIG. 3 illustrates a side view of the example ventilation duct and a front view of the example ventilation duct, according to some embodiments.

FIG. 4 illustrates a perspective view and a cutaway view of the example ventilation duct, according to some embodiments.

FIG. 5 is an illustration of an example system, according to some embodiments.

FIG. 6 is an illustration of an example system, which is similar to the system of FIG. 5, but omits the example ventilation duct for ease of illustration.

FIG. 7 is an illustration of an example ventilation duct, according to some embodiments.

FIG. 8 is an illustration of an example pluggable module and an example optical patch cord, according to some embodiments.

FIG. 9 is an illustration of the example electrical equipment 530, which is discussed with respect to FIGS. 1, 5, and 6.

While the system of the present application is susceptible to various modifications and alternative forms, specific embodiments thereof have been shown by way of example in the drawings and are herein described in detail. It should be understood, however, that the description herein of specific embodiments is not intended to limit the system to the particular forms disclosed, but on the contrary, the intention is to cover all modifications, equivalents, and alternatives falling within the spirit and scope of the present application as defined by the appended claims.

### DETAILED DESCRIPTION

Illustrative embodiments of the system of the present application are described below. In the interest of clarity, not all features of an actual implementation are described in this specification. It will of course be appreciated that in the development of any such actual embodiment, numerous implementation-specific decisions must be made to achieve the developer's specific goals, such as compliance with system-related and business-related constraints, which will vary from one implementation to another. Moreover, it will be appreciated that such a development effort might be complex and time-consuming but would nevertheless be a routine undertaking for those of ordinary skill in the art having the benefit of this disclosure.

Various embodiments include a duct mounted on the outside of a piece of electronic equipment to channel cooling air around the part of a pluggable optoelectronic module that protrudes from the faceplate of the electronic equipment. The faceplate of the electronic equipment may have ventilation openings in proximity to the pluggable module to allow cooling air into the equipment. A fan may be implemented in the electronic equipment and may be used to draw air through the ventilation openings into the equipment. The velocity of the air that passes through the duct in close proximity to the protruding pluggable module is greater than it would be if there were no duct to channel the air. Thus, the duct may use increased convection to help cool the pluggable module.

Various embodiments include a duct or other structure, which may be installed around or adjacent to the part of the pluggable module that protrudes from the faceplate of the equipment. One end of the duct may be located in close proximity to the faceplate of the equipment or may be an integral part of the faceplate of the equipment. Some or all of the ventilation openings in the faceplate which draw cooling air into the equipment may be covered by the duct.

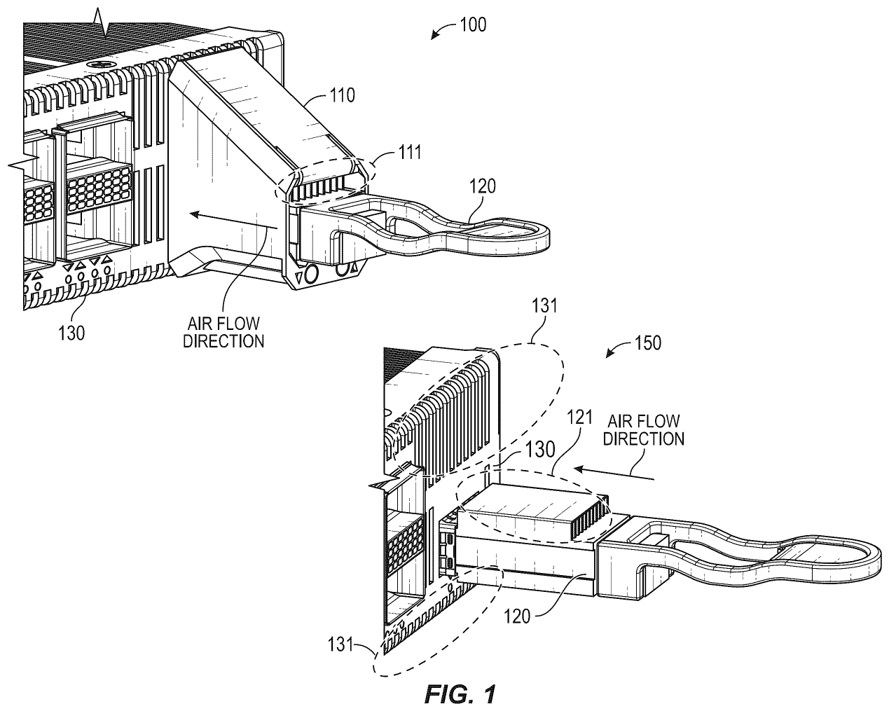

FIG. 1 is an illustration of an example system 100, including a ventilation duct 110, according to some embodiments. FIG. 1 also illustrates an example system 150, which omits the ventilation duct 110 for ease of illustration of ventilation openings 131.

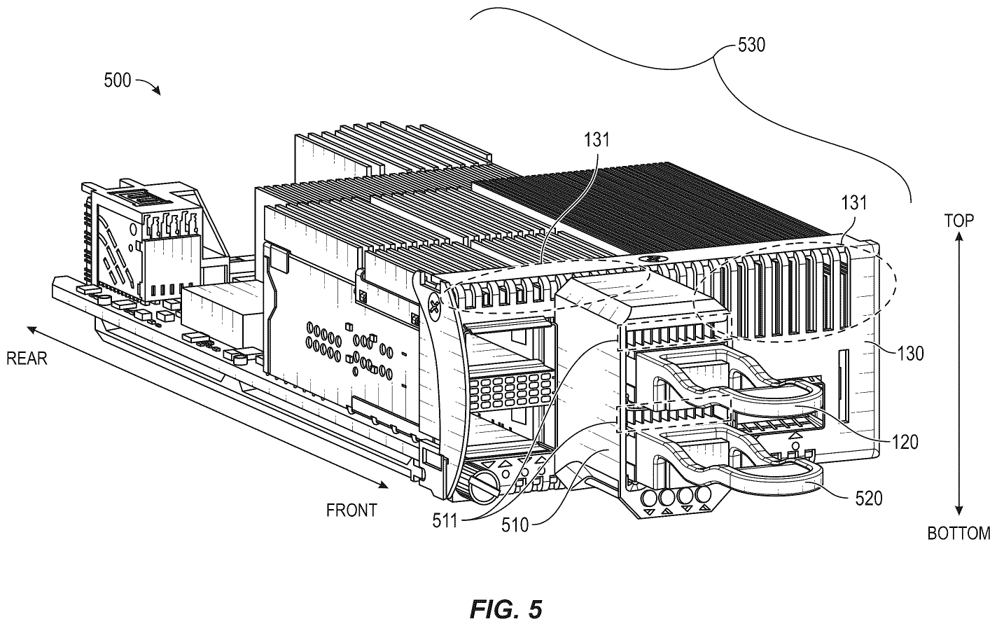

In this example, an optoelectronic pluggable module 120 is mated with electronic equipment, and the electronic equipment is shown by the faceplate 130. An example of electronic equipment includes electronic equipment 530 of FIG. 5. For instance, the pluggable module 120 may be inserted into an opening of the faceplate 130 to make an electrical connection between electrical contacts (not shown) of the pluggable module 120 and electrical contacts (not shown) within the electronic equipment. Furthermore, the electronic equipment may include a fan (not shown), which may cause airflow from the ambient atmosphere, through ventilation openings 131 in the faceplate 130, and toward the rear of the electronic equipment. The electronic equipment may exhaust the airflow in any appropriate manner.

In the present example and during operation of system 100, the airflow may travel in the direction of the arrow, through the ventilation opening 111, through fins of the heatsink 121 and over heatsink 121, through the ventilation openings 131, and toward the rear of the electronic equipment. In the present example, the ventilation duct 110 may direct airflow in such a manner in order to ensure some amount of airflow contacts the pluggable module 120, thereby providing some amount of cooling.

Further in the present example, the ventilation duct 110 may be designed to accommodate a single pluggable module 120, though the scope of implementations may include other ventilation ducts that are designed to accommodate more than one pluggable module, such as discussed in more detail with respect to FIGS. 5-7. The ventilation duct 110 may be constructed of any appropriate material, such as plastic, ceramic, rubber, silicone, and/or the like. In some examples, the ventilation duct 110 may be constructed of an insulating material rather than a conducting material (e.g., metal), though the scope of implementations may use any appropriate material.

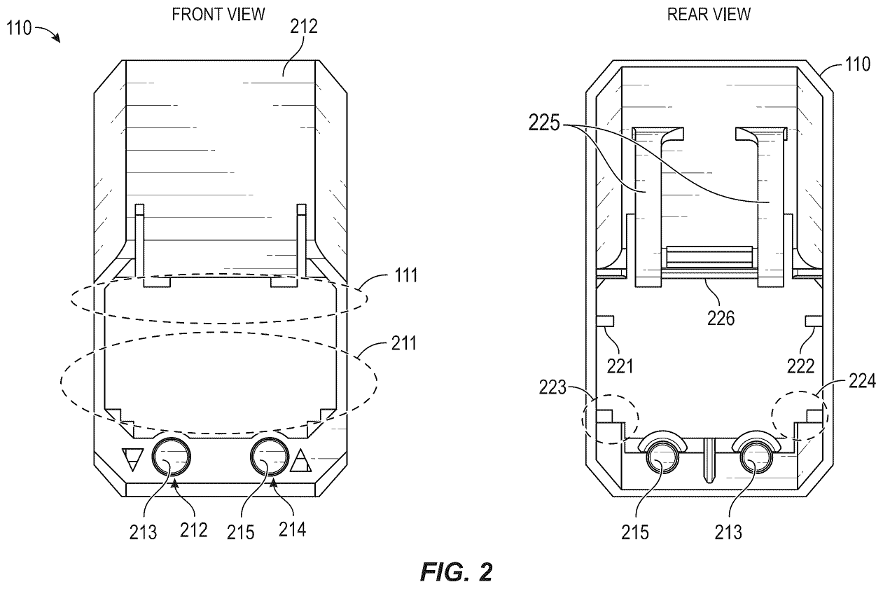

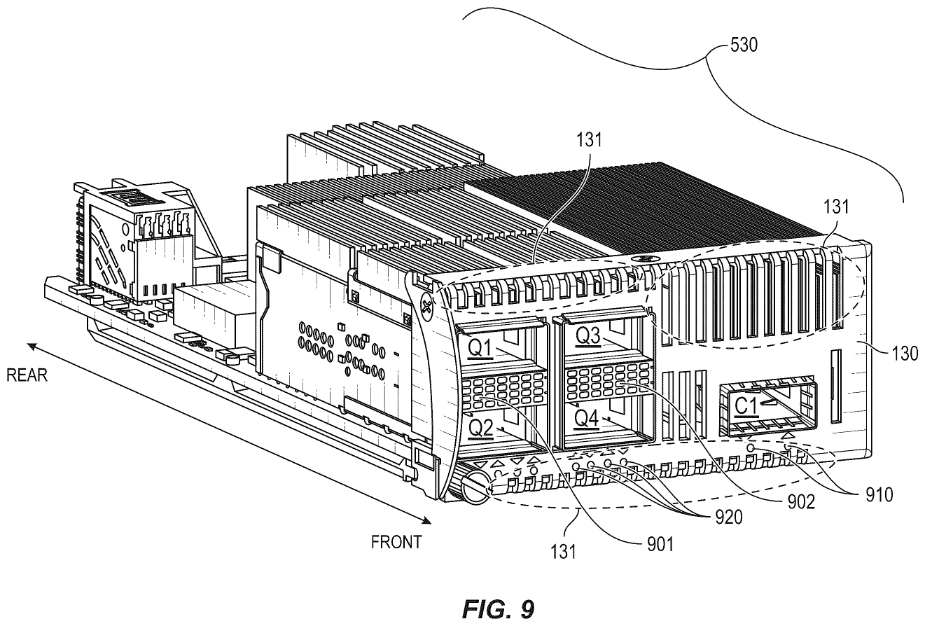

FIG. 2 is an illustration of the example ventilation duct 110 according to a front view and a rear view, according to some embodiments. Looking at the front view first, the housing 212 is fashioned to include the ventilation opening 111 and an opening 211, where the opening 211 may be configured to accommodate a pluggable module, such as pluggable module 120. The front view of ventilation duct 110 also includes holes 212, 214, which may extend through a depth of the ventilation duct 110 (e.g., from the front to the rear) and may accommodate translucent material 213, 215. The translucent material 213, 215 may allow for light signals, emitted from the faceplate 130, to appear at the front of ventilation duct 110. For instance, the translucent material 213 may be designed to pass light signals indicating downlink data, and the translucent material 215 may be designed to pass light signals indicating uplink data. The light signals may be provided by the electronic equipment, such as may be associated with the faceplate 130. Example lights for emitting light signals from faceplate 130 are illustrated as lights 910 of FIG. 9.

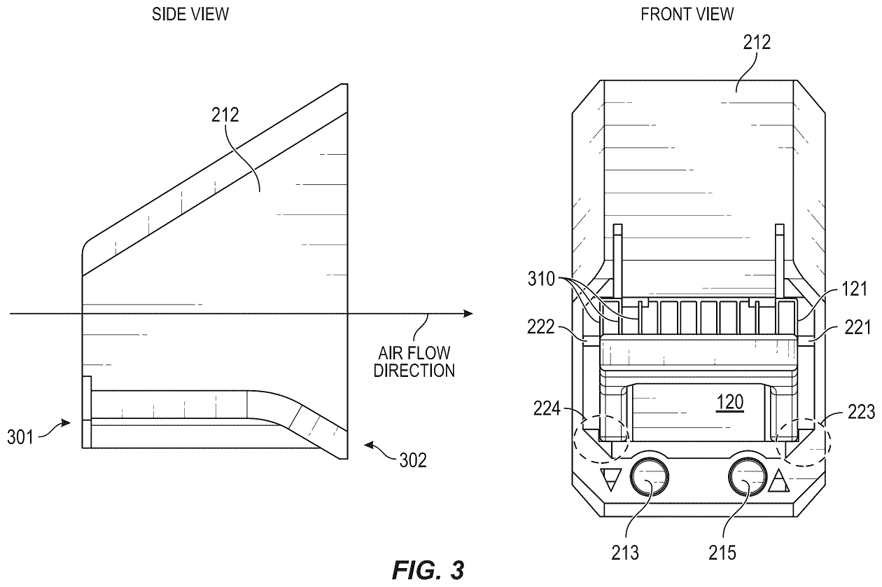

Looking at the rear view, there are tabs 221, 222, which define a boundary between the ventilation opening 111 and the opening 211. More particularly, tabs 221, 222 extend laterally from the sides of the housing 212. Tab 221 and shelf 223 may accommodate the physical form factor of the pluggable module 120 on one side, and tab 222 and shelf 224 may accommodate the physical form factor of the pluggable module 120 on the other side. Shelves 223 and 224 may be configured to support a bottom surface of the pluggable module 120. Accommodating the physical form factor of the pluggable module 120 is described in more detail with respect to FIG. 3.

Inside of the housing 212, there may be formed springs 225 and ceiling 226. The springs 225 and ceiling 226 may be designed to provide some amount of force on the bottom of springs 225 and bottom of the ceiling 226 so that when a pluggable module 120 is inserted within ventilation duct 110, the springs 225 and the ceiling 226 may provide some amount of pressing force on top of the pluggable module 120, thereby providing a friction fit between ventilation duct 110 and pluggable module 120. The various components of the ventilation duct 110, such as housing 212, tabs 221, 222, springs 225, ceiling 226, and the like may be formed as a single piece or may be formed as separate pieces that are coupled together.

FIG. 3 illustrates a side view of ventilation duct 110 and a front view of ventilation duct 110, according to some embodiments. The side view illustrates the front end 301 and the rear end 302 of the housing 212. For instance, the front views of FIGS. 2-3 show a view directly facing the front end 301, and the rear view of FIG. 2 shows a view directly facing the rear end 302. A direction of airflow during normal operation is illustrated by an arrow, where the airflow may enter the ventilation opening 111 in the front end 301 and may exit the rear end 302 into one or more ventilation opening 131 (FIG. 1) of the electronic equipment. For instance, during assembly, the rear end 302 may be placed against or nearly against the faceplate 130 of the electrical equipment so that the rear end 302 covers one or more ventilation openings 131.

The front view of FIG. 3 illustrates the housing 212 accommodating a pluggable module 120 inserted therein. The pluggable module 120 is supported on its bottom side by shelves 223, 224. The pluggable module 120 may also receive further support from the tabs 221, 222. The heatsink 121 includes a multitude of fins, where some of those spends are illustrated as fins 310. The fins 310 create tunnels for the airflow, which in the front view, goes into the page. The top surface of the heatsink 121 may rest against the bottom of the springs 225 and the ceiling 226.

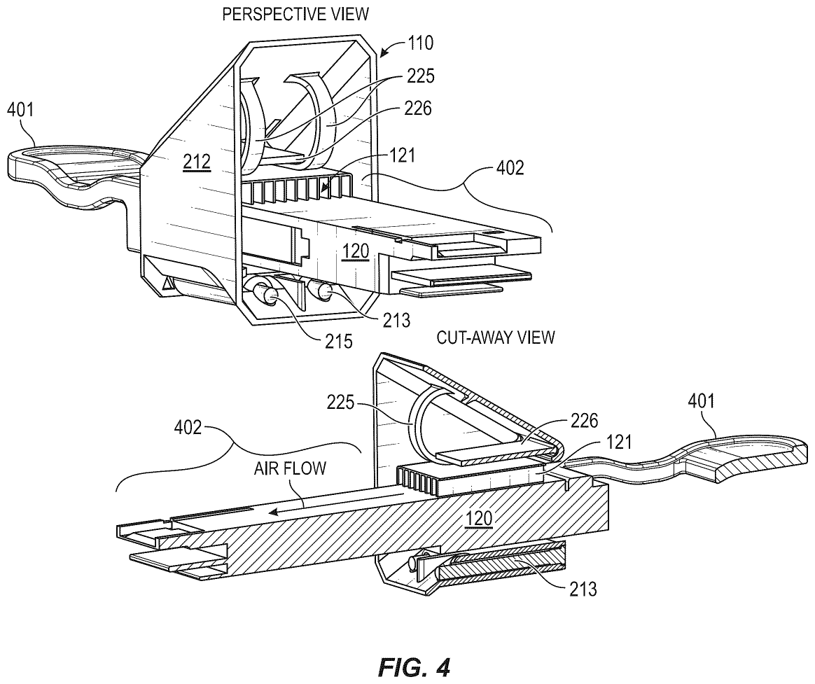

FIG. 4 illustrates a perspective view and a cutaway view of the ventilation duct 110, according to some embodiments. The perspective view illustrates the pluggable module 120 inserted into the ventilation duct 110. The pluggable module 120 includes a handle portion 401 and an inserted portion 402. During installation of the ventilation duct 110, the pluggable module 120 may be inserted through the front end 301, inserted end 402 first, so that the electrical contacts of the inserted portion 402 make electrical connection with corresponding contacts (not shown) within the electronic equipment. Example airflow is shown by an arrow in the cutaway view, as that airflow would enter from the ambient atmosphere through the ventilation opening 111, through the heatsink 121 and out through the rear end 302 and into one or more ventilation openings 131 of the faceplate 130.

FIG. 4 illustrates that the housing 212 has an opening from the front side 301 to the rear side 302 that is configured to accommodate pluggable module 120. Such opening may include both openings 111 and 211. Further, the opening from the front side 301 to the rear side 302 is configured to define the ventilation opening 111 to cause airflow from the front side 301 to the rear side 302 to be in contact with the pluggable module 120 when the pluggable module 120 is inserted within the ventilation duct 110. The airflow in this example is in contact with the fins 310 of the heat sink 121. In another embodiment in which a pluggable module does not include a heat sink, the airflow may contact the outside surfaces of such pluggable module.

In the examples of FIGS. 1-4, the ventilation duct 110 is shown as being separate from the pluggable module 120 and separate from the faceplate 130. However, the scope of embodiments is not so limited. Rather, other embodiments may implement the ventilation duct 110 as integral to the pluggable module 120, such as being formed as part of a housing of the pluggable module 120 or permanently affixed (e.g., adheased) to the pluggable module 120. In other embodiments, the ventilation duct 110 may be implemented as integral to the faceplate 130, such as being formed as part of the faceplate 130 or being permanently affixed (e.g., adheased) to the faceplate 130.

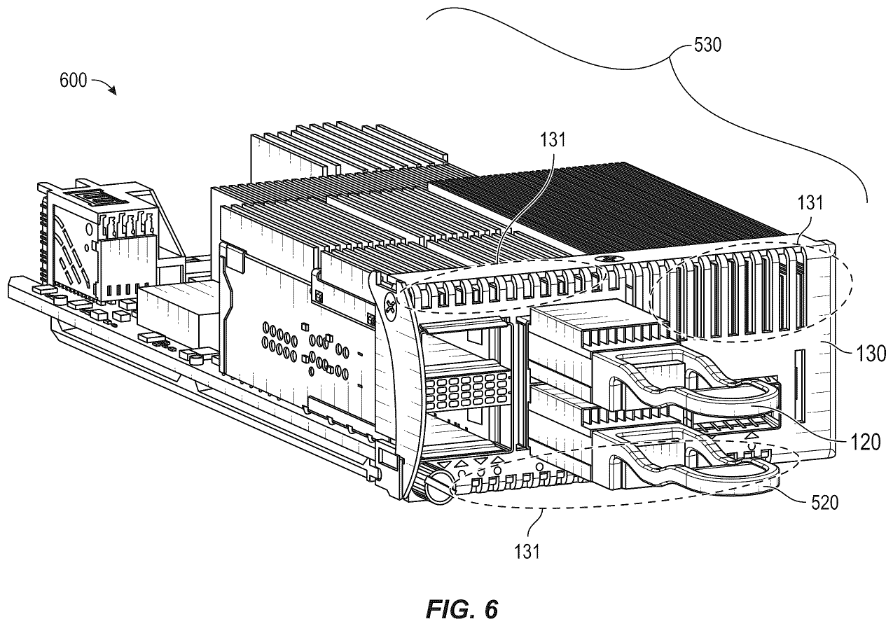

FIG. 5 is an illustration of an example system 500, according to some embodiments. More specifically, FIG. 5 illustrates example ventilation duct 510, which may accommodate up to two pluggable modules 120, 520. The pluggable modules 120, 520 are inserted into electronic equipment 530. Electronic equipment 530 may be the same as or different from the electronic equipment of FIG. 1 and may further include a fan (not shown) to cause airflow from the ambient atmosphere, through the ventilation openings 131, and to the rear of electronic equipment 530. In other words, the direction of airflow in the example of FIG. 5 is front to rear. FIG. 6 is an illustration of example system 600, which is similar to system 500, but omits ventilation duct 510 for ease of illustration.

Electronic equipment 530 includes faceplate 130, which also includes ventilation openings 131. As noted above, the ventilation openings 131 may allow airflow from the ambient atmosphere, through the ventilation openings 131, and to the rear of the electronic equipment 530. The pluggable module 520 may be the same as or similar to pluggable module 120. Ventilation duct 510 has a rear side that is configured to fit against the faceplate 130 and cover or at least partially cover some or all of the ventilation openings 131. Ventilation duct 510 has a front side that is configured to receive pluggable modules 120, 520.

In this example, the ventilation duct 510 allows for the pluggable modules 120, 520 to be arranged vertically with respect to each other. Ventilation duct 510 accommodates two ventilation openings 511, which allow airflow to move from the ambient atmosphere, through the fins of the heatsinks of pluggable modules 120, 520, through the ventilation openings 131, and to the rear of electronic equipment 530.

Electronic equipment 530 may include any appropriate electronic device. In one example, electronic equipment 530 may include a storage system, computing system, networking system, a combination of one or more of storage, computing, and networking, and/or the like. For instance, in one example, electronic equipment 530 may include networking equipment (e.g., a router, switch, gateway, or similar device), which receives electronic data signals at one or more ports, performs networking operations on those electronic data signals, and outputs the electronic data signals at one or more ports. The pluggable modules 120, 520 may receive optical data signals, convert those optical data signals to electronic data signals, and provide those electronic data signals to the electronic equipment 530.

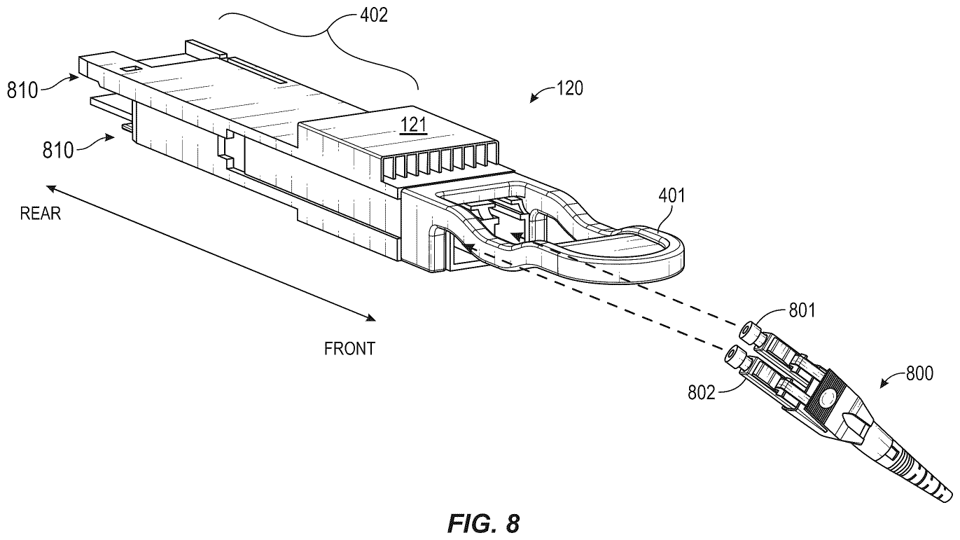

Furthermore, the pluggable modules 120, 520 may receive electronic data signals from the electronic equipment 530, convert those electronic data signals to optical data signals, and transmit those optical data signals to other devices (not shown). Each of the pluggable modules 120, 520 may have ports for optical patch cords (such as in FIG. 8), which may be used for transmitting and receiving optical data. Conversion of optical data signals to electronic data signals and vice versa may create heat in the pluggable modules 120, 520. The ventilation ducts 110, 510 may be used to provide cooling for the pluggable modules 120, 520.

In the example of FIG. 5, the ventilation duct 510 is configured to be approximately a same vertical dimension as the faceplate 130, thereby allowing ventilation duct 510 to enclose ventilation openings 131 on both the top of the faceplate 130 and the bottom of the faceplate 130. Ventilation openings 131 on the bottom are more clearly illustrated in FIG. 1 and FIG. 6.

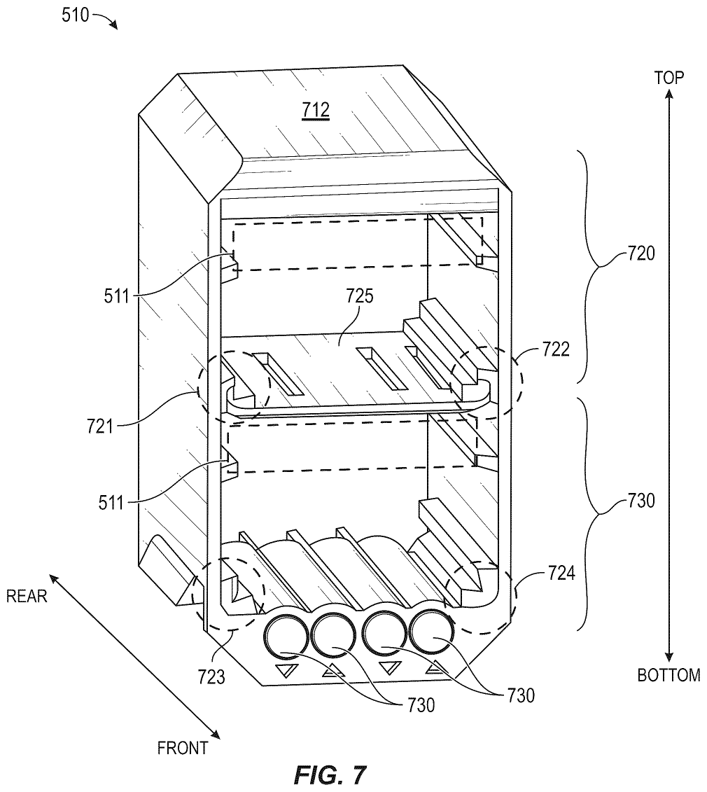

FIG. 7 is an illustration of example ventilation duct 510, according to some embodiments. FIG. 7 provides a perspective view, showing a top portion 720 and a bottom portion 730. The top portion 720 may be configured to accommodate pluggable module 120, such as illustrated in FIG. 5, and bottom portion 730 may be configured to accommodate pluggable module 520, such as illustrated in FIG. 5.

Top portion 720 includes shelves 721, 722, which are configured to accommodate a bottom surface of pluggable module 120. Similarly, bottom portion 730 includes shelves 723, 724, which are configured to accommodate a bottom surface of pluggable module 520. When pluggable module 120 is inserted in top portion 720 and when pluggable module 520 is inserted in bottom portion 730, the ventilation duct 510 defines ventilation openings 511. For instance, one ventilation opening 511 is at the top of top portion 720, and another ventilation opening 511 is at the top of bottom portion 730. The direction of airflow may be from the ambient atmosphere from the front to the rear. Divider portion 725 may define the boundary between the top portion 720 and the bottom portion 730.

FIG. 7 illustrates that the housing 712 includes openings from the front side to the rear side to accommodate both pluggable modules 120, 520. For instance, top portion 720 defines an opening from the front side to the rear side of housing 712 to accommodate pluggable module 120, and bottom portion 730 defines an opening from the front side to the rear side of housing 712 to accommodate pluggable module 520. Both the top portion 720 and the bottom portion 730 define ventilation openings 511 to cause airflow from the front side to the rear side in contact with respective pluggable modules 120, 520. For instance, the airflow through the ventilation openings 511 may contact the heatsinks of the pluggable modules 120, 520. In an example in which a given pluggable module does not have a heatsink, the airflow would be in contact with outside surfaces of the given pluggable module via the ventilation openings 511.

Ventilation duct 510 may also include translucent material 730. Similarly to translucent material 213, 215 (FIG. 2), translucent material 730 may allow for light signals from the faceplate 130 to be emitted at the front side of ventilation duct 510 to indicate uplink and downlink data activity. For instance, the faceplate 130 may include one or more lights, where the lights may provide the light signals, and the individual portions of the translucent material 730 may correspond to individual ones of the lights on the faceplate 130. Example lights, which may be used to provide light signals from the faceplate 130 are illustrated as lights 920 in FIG. 9.

As with ventilation duct 110, ventilation duct 510 may be constructed of any appropriate materials, such as plastic, ceramic, and/or the like. Furthermore, ventilation duct 510 may be constructed as a single piece or as multiple pieces as appropriate.

FIG. 8 is an illustration of example pluggable module 120 and optical patch cord 800, according to some embodiments. As noted above, pluggable module 520 may be similar to or different from pluggable module 120. In this example, pluggable module 120 generally conforms to a QSFP-DD type 2B module, according to the QSFP-DD MSA. However, the scope of implementations may accommodate use of any optoelectronic pluggable module, whether now known or later developed. The rear of pluggable module 120 has electrical contacts 810 to make electrical connection with one or more electrical contacts (not shown) of electronic equipment, such as electronic equipment 530.

At the front of pluggable module 120 are physical ports, which are configured to receive the individual optical cable terminations 801, 802 of optical patch cord 800. Insertion of the optical cable terminations 801, 802 is illustrated using arrows. When optical patch cord 800 is operably coupled to the pluggable module 120, the individual optical cable terminations 801, 802 may transmit and receive optical data to corresponding optical receivers and transmitters (not shown) inside pluggable module 120. In one example, each of the optical cable terminations 801, 802 may be unidirectional so that each of the optical cable terminations 801, 802 either transmits or receives. In another example, each of the optical cable terminations 801, 802 may be bidirectional.

As noted above, example ventilation ducts 110, 510 may be configured to accommodate one or more pluggable modules, such as pluggable modules 120 and 520.

FIG. 9 is an illustration of example electrical equipment 530, which is discussed above with respect to FIGS. 1, 5, and 6. Example electrical equipment 530 includes five different ports for receiving pluggable modules. The ports are labeled Q1-Q4 and C1. In the example of FIG. 1, pluggable module 120 is plugged into port C1. In the example of FIG. 5, pluggable module 120 is plugged into port Q3, and pluggable module 520 is plugged into port Q4. Although not shown, it is understood that pluggable modules 120, 520 may be plugged into ports Q1, Q2 similarly to the arrangement shown in FIG. 5.

Furthermore, FIG. 9 illustrates additional ventilation openings 901, 902 at the front of electronic equipment 530. For instance, ventilation openings 902 are obscured by ventilation duct 510 in FIG. 5 and are obscured by pluggable modules 120, 520 in FIG. 6. Nevertheless, ventilation openings 901 and 902 may allow for further airflow from ambient air at the front to the rear of electronic equipment 530. Thus, in the example of FIG. 5, the ventilation duct 510 would accommodate further airflow via ventilation openings 902 as well as via ventilation openings 131 on the top and the bottom of the faceplate 130. Additionally, in an example in which pluggable modules (e.g., 120, 520) are inserted into ports Q1, Q2, a ventilation duct (e.g., ventilation duct 510) may be used to accommodate airflow via ventilation openings 901.

Lights 910 may provide an indication of uplink and downlink activity for port C1. In one example, lights 910 may align with translucent material 213, 215 (FIG. 2), and translucent material 213, 215 may make the light signals from lights 910 available at the front side of ventilation duct 110. Similarly, lights 920 may align with translucent material 730 (FIG. 7) to make the light signals from lights 920 available at the front side of ventilation duct 510.

Of course, the scope of implementations is not limited to any particular electrical equipment, such as electrical equipment 530. Various ventilation ducts, such as ventilation ducts 110, 510, may be used with any appropriate electrical equipment that is configured to receive any appropriate pluggable module. For instance, any appropriate electrical equipment having ventilation openings, which may be enclosed or partially enclosed by ventilation ducts, and configured to service one or more pluggable modules, may be used in various embodiments.

Additionally, although a fan is not shown in FIG. 9, it is understood that the electronic equipment 530 may include a fan or other air moving device. For instance, the fan or other air moving device may be configured to draw ambient air from the front of the electronic equipment 530, such as through ventilation openings 131, 901, 902, and direct the airflow toward the rear of the electronic equipment 530. However, in some embodiments, the air may be exhausted in any appropriate manner, such as through the rear, through the top, or through the bottom of the electronic equipment 530.

Various embodiments may include a ventilation duct, partially or completely surrounding a pluggable optoelectronic module, which effectively couples the air directly adjacent to the module with the airflow being drawn into the electronic equipment into which the module is plugged. Examples of ventilation ducts are described above with respect to ventilation ducts 120, 520. Examples of electronic equipment are described above with respect to electronic equipment 530.

Various embodiments may include a ventilation duct which substantially bridges a gap between a heatsink on a pluggable optoelectronic module and the faceplate of the electronic equipment into which the module is plugged. Such example ventilation duct may effectively prevent some ambient air from directly entering ventilation openings in the faceplate itself, instead coupling the airflow through the heatsink of the module with the air being drawn through the heatsink of the module and then into the ventilation openings of the faceplate.

Various embodiments may include a ventilation duct that is attached to the faceplate of the electronic equipment into which the module is plugged.

Various embodiments may include a ventilation duct that is integrated into the faceplate or attached to the faceplate of the electronic equipment into which the module is plugged. Various embodiments may include a ventilation duct that is mounted on the pluggable optoelectronic module. Various embodiments may include a ventilation duct that is attached to the pluggable optoelectronic module or is integrated into a housing of the pluggable optoelectronic module.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated that the conception and specific embodiment disclosed may be readily utilized as a basis for modifying or designing other structures for carrying out the same purposes of the present invention. It should also be realized that such equivalent constructions do not depart from the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

What is claimed is:

1. A system comprising:
a housing having a front side and a rear side; and
an opening in the housing from the front side to the rear side, and wherein the opening is configured to accommodate a pluggable module;
further wherein the opening is configured to define a ventilation opening to cause airflow from the front side to the rear side in contact with the pluggable module.

2. The system of claim 1, further comprising:
a spring enclosed within the housing; and
a ceiling enclosed within the housing, wherein the spring and ceiling are configured to provide a friction fit for an outside surface of the pluggable module.

3. The system of claim 1, further comprising:
translucent material extending from the front side of the housing to the rear side of the housing.

4. The system of claim 3, wherein the translucent material is configured to transmit light signals from the rear side of the housing to the front side of the housing.

5. The system of claim 3, wherein the translucent material is configured to correspond to a placement of a light on a faceplate of electronic equipment into which the pluggable module is configured to be plugged.

6. The system of claim 1, further comprising:
the pluggable module, wherein the housing is integral to the pluggable module.

7. The system of claim 1, wherein the housing is integral to a faceplate of electronic equipment into which the pluggable module is configured to be inserted.

8. The system of claim 1, further comprising:
an additional opening in the housing from the front side to the rear side, wherein the additional opening is configured to accommodate an additional pluggable module.

9. The system of claim 1, further comprising:
shelves, extending from the front side of the housing to the rear side of the housing, wherein the shelves are configured to support a bottom surface of the pluggable module.

10. A system comprising:
a housing having a front side and a rear side; and
an opening in the housing from the front side to the rear side, and wherein the opening is configured, at the rear side of the housing, to cover a first ventilation opening on a faceplate of an electronic equipment;
further wherein the opening is configured to define a second ventilation opening, at the front side of the housing, to cause airflow from the front side of the housing to the first ventilation opening.

11. The system of claim 10, wherein the opening in the housing is configured, at the rear side of the housing, to cover the first ventilation opening on the faceplate at a top side of the housing and is further configured to cover a third ventilation opening on the faceplate of the electronic component at a bottom side of the housing.

12. The system of claim 10, wherein the housing comprises a single piece of plastic.

13. The system of claim 10, wherein the housing is not permanently attached to the faceplate and is not integral with the faceplate.

14. The system of claim 10, further comprising:
the faceplate, wherein the housing is integral with the faceplate.

15. The system of claim 10, wherein the opening in the housing from the front side to the rear side is configured to accommodate a single optoelectronic pluggable module.

16. The system of claim 10, wherein the opening in the housing from the front side to the rear side is configured to accommodate a plurality of optoelectronic pluggable modules.

17. The system of claim 10, further comprising:
a spring enclosed within the housing; and
a ceiling enclosed within the housing, wherein the spring and ceiling are configured to provide a friction fit for an outside surface of an optoelectronic pluggable module.

18. The system of claim 10, further comprising:
translucent material, extending from the front side of the housing to the rear side of the housing, wherein the translucent material is configured to correspond to a light on the faceplate.

19. The system of claim 10, further comprising:
an optoelectronic module, configured to be inserted into the faceplate, wherein the housing is attached to the optoelectronic module.

20. A system comprising:
a housing having a front side, a rear side, a top side, and a bottom side;
first translucent material disposed within the housing and extending from the front side to the rear side of the housing; and
second translucent material disposed within the housing and extending from the front side to the rear side of the housing;
wherein the housing is configured at the rear side to cover a plurality of ventilation openings on a faceplate of electronic equipment, and wherein the housing is configured at the front side to accommodate insertion of an optoelectronic pluggable module to be inserted through the housing from the front side to the rear side and into the faceplate of the electronic equipment, further wherein the housing is configured to define an additional ventilation opening to cause airflow to contact an outside surface of the optoelectronic pluggable module, and further wherein the first translucent material and the second translucent material are configured to transmit light signals from the faceplate to the front side of the housing.
